(19) United States
(12) Patent Application Publication
(10) Pub. No.: US 2019/0064405 A1
(43) Pub. Date: Feb. 28, 2019

(54) OPTICAL ELEMENT AND OPTICAL ASSEMBLY COMPRISING SAME

(71) Applicant: CARL ZEISS SMT GMBH, Oberkochen (DE)

(72) Inventors: Christian GRASSE, Garching (DE); Oliver DIER, Lauchheim (DE); Joern WEBER, Aalen (DE); Ralf WINTER, Schwaebisch Gmuend (DE)

(21) Appl. No.: 16/170,298

(22) Filed: Oct. 25, 2018

Related U.S. Application Data
(63) Continuation of application No. PCT/EP2017/057277, filed on Mar. 28, 2017.

(30) Foreign Application Priority Data
Apr. 28, 2016 (DE) 10 2016 207 307.9

(51) Int. Cl. G02B 5/08; G02B 1/16; G02B 1/14; G21K 1/06; G03F 7/20

(52) U.S. Cl. CPC G02B 5/0891; G02B 1/16; G21K 2201/067; G21K 1/062; G03F 7/7015; G02B 1/14

(57) ABSTRACT

An optical element (14), in particular for EUV lithography, includes a substrate (15), a reflective coating (16) arranged on the substrate (15), and an electrically conductive coating (19) extending between the substrate and the reflective coating, and having at least one first layer (22a) under tensile stress and at least one second layer (22b) under compressive stress. The electrically conductive coating has at least one section (20) that extends on the substrate laterally beyond the reflective coating. Also disclosed is an optical assembly, in particular an EUV lithography system, provided with at least one optical element of this type.

### CROSS REFERENCE TO RELATED APPLICATIONS

This is a Continuation of International Application PCT/EP2017/057277 which has an international filing date of Mar. 28, 2017, the disclosure of which is incorporated in its entirety into the present Continuation by reference. This Continuation additionally claims the priority of the German patent application DE 10 2016 207 307.9 of Apr. 28, 2016, the entire disclosure content of which is incorporated by reference into the present Continuation.

### FIELD OF INVENTION

The invention relates to an optical element, in particular for EUV lithography, comprising: a substrate, a reflective coating applied on the substrate, and an electrically conductive coating extending between the substrate and the reflective coating. The invention also relates to an optical assembly, in particular an EUV lithography system, comprising at least one such optical element.

### BACKGROUND

A reflective optical element as described further above has been disclosed by WO 2008/034582 A2. As a result of the formation of photoelectrons, in particular of secondary electrons, during the irradiation of the optical element with EUV radiation, charges are generated at that surface of the reflective coating which faces the environment, which charges typically cannot be dissipated via the substrate since the latter either is electrically insulating or has a significantly lower electrical conductivity in comparison with the reflective coating, typically a multilayer coating. The electrically conductive coating or layer described therein is therefore electrically contactable for grounding, for applying a defined voltage or for conducting away a photocurrent.

The electrically conductive layer can be electrically contacted in order to carry out grounding of the optical element or to connect the latter to a defined potential. In this way, the charges can be transported away from the optical element and an electrostatic charging of the optical element can be avoided. The charges transported away from the optical element can also be used to measure a photocurrent that can be used to draw conclusions about the degree of contamination of the reflective surface of the optical element.

WO 2008/034582 A2 proposes forming the electrically conductive coating from a single layer composed of a metal, for example composed of gold, nickel, etc., or composed of alloys. Alternatively, the electrically conductive coating can also consist of a (further) multilayer system.

WO 2006/033442 A1 describes a reflective mask in which an electrically conductive layer is mounted at the rear side of the substrate facing away from the reflective coating, in order to ground the substrate and in this way to protect the substrate against an electrostatic charging. A further electrically conductive layer, which electrically conductively continues the layer at the rear side of the substrate, covers the side surfaces of the substrate and also the front side of the substrate, at which inter alia the reflective coating and a structured absorber layer are applied.

JP 2007194406 A describes a mirror having a reflective multilayer coating, which is suitable for grounding the multilayer coating or for applying an electrical potential to the mirror. For this purpose, an electrically conductive layer is applied between the multilayer coating and the substrate, and extends to a mount at the side surface of the mirror, at which a holder for the mirror is mounted. In this way, the multilayer coating can be grounded without the reflective surface of the multilayer coating being damaged and the optical properties of the mirror thereby being impaired.

### SUMMARY

It is an object of the invention to provide an optical element and an optical assembly in which the optical properties of the optical element are not impaired by the electrically conductive coating.

This object is achieved with an optical element of the type mentioned in the introduction wherein the electrically conductive coating has at least one first layer under tensile stress and at least one second layer under compressive stress.

With the use of an electrically conductive coating in the form of an individual layer composed of a highly conductive, generally metallic, material having a layer thickness typically of the order of magnitude of e.g. a hundred nanometers or more, the layer stress of the electrically conductive coating can result in a change in the figure, i.e. the surface shape of the substrate and/or of the reflective surface of the reflective coating, such that optical aberrations can occur which can impair the optical properties of the mirror, in particular the wavefront of the reflected EUV radiation, or which possibly necessitate a complex correction method in order to change the figure of the substrate before the electrically conductive coating is actually applied. High layer stresses, for example in the form of tensile stresses, occur particularly in the case of electrically conductive coatings which consist of a noble metal, e.g. of gold, in order to produce the highest possible conductivity and chemical resistance of the electrically conductive coating.

By using an electrically conductive coating having a first layer under tensile stress and a second layer under compressive stress, it is possible to reduce the deformation of the substrate and thus of the surface shape of the optical element on account of layer stresses in the electrically conductive coating. For this purpose, the material of the (at least one) first layer, the thickness and possibly the manner of application of the first layer and also the material of the (at least one) second layer, the thickness and possibly the manner of application of the second layer can be chosen such that the tensile stress of the first layer substantially compensates for the compressive stress of the second layer.

Such a compensation can be carried out in a manner analogous to that described in U.S. Pat. No. 8,564,925 B2, wherein an electrically conductive coating of a wafer chuck has at least one first layer having a tensile stress and at least one second layer having a compressive stress, which are ideally coordinated with one another in such a way that overall tensile and compressive stresses compensate for one another.

As an alternative to a (virtually) complete compensation of the layer stress, it is possible to coordinate the tensile stress and the compressive stress of the layers of the electrically conductive coating with one another such that a desired, predefined resulting layer stress (tensile or compressive stress) of the electrically conductive coating is produced. The predefined layer stress of the electrically conductive coating can be chosen for example in such a way that a layer stress that arises on account of the coating process in the reflective coating is compensated for, or if appropriate compensated for to the greatest possible extent.

In one embodiment, the first and/or the second layer are/is formed from a metallic material or from an alloy. As has been described further above, metallic materials, in particular noble metals, and if appropriate alloys thereof, have a high electrical conductivity and a good chemical resistance, such that these materials are particularly well suited for the electrically conductive coating.

The following group of materials and the alloys thereof are particularly suitable as materials for the first and/or the second layer of the electrically conductive coating on account of their electrical conductivity: silver, copper, gold, aluminum, rhodium, iridium, tungsten, molybdenum, cobalt, nickel, ruthenium, indium, osmium, iron, platinum, palladium, chromium, tantalum, titanium, Zr, Re.

The fact of whether a compressive or a tensile stress occurs in the first and/or the second layer can be influenced by the respective production method or coating method when applying the respective layer and by the layer material used. In other words, there are materials which tend rather to the formation of tensile stresses and materials which tend rather to the formation of compressive stresses, wherein the formation of a tensile or compressive stress can be influenced by the production method. Generally, production methods should be understood to mean coating methods in the form of “Physical Vapor Deposition” (PVD) methods, such as e.g. thermal evaporation or Ebeam/electron beam evaporation, ion beam & magnetron sputtering or pulsed laser deposition, or coating methods based on “Chemical Vapor Deposition” (CVD).

The material of the first layer can be selected for example from the group above and is produced by a coating method that typically produces tensile stresses. By way of example, the first layer having the tensile stress can consist of gold and be produced using electron beam evaporation.

The material of the second layer can likewise be selected from the above group and be applied during coating by a method which typically produces a compressive stress. By way of example, the second layer can be formed from ruthenium and be applied by sputtering, since this coating method typically produces a compressive stress. As has been described further above, the material of the first layer and the material of the second layer and also the layer thicknesses are typically coordinated with one another such that the desired resulting layer stress of the electrically conductive coating is established, which can be almost zero, in particular. The resulting layer stress of the electrically conductive coating is generally not dependent on the order of the layers, that is to say that the second layer having a compressive stress can be applied on the first layer having a tensile stress, or vice-versa.

In a further embodiment, the electrically conductive coating comprises at least one barrier layer that is arranged between the first layer and the second layer. The barrier layer is likewise formed from an electrically conductive material and is intended to prevent the diffusion of the material of the first layer into the second layer, and vice-versa. If the electrically conductive coating has two or more first layers and two or more second layers, then a barrier layer can be formed between in each case two adjacent first and second layers. Since the barrier layer is intended merely to prevent the diffusion of the materials between the first and second layers, the barrier layer can be very thin and have for example a thickness of less than e.g. approximately 1 nm, such that the conductivity of the electrically conductive coating is not significantly impaired, even if the material of the barrier layer is not electrically conductive. An advantage of the barrier layer is that a layer thickness change on account of diffusion processes and thus a change in the surface shape (see above) are prevented.

In a further embodiment, a barrier layer is arranged between the reflective coating and the electrically conductive coating. In this case, the barrier layer serves to prevent the diffusion of the materials of the reflective coating into the electrically conductive coating, and vice-versa, in order in this way to avoid an undesired change in the layer thickness of the layers involved.

In both cases described above, the materials for the barrier layer are preferably selected from the group: W, Ta, Y, Mo, Zr, Ti, Hf, Sc, alloys and/or chemical compounds thereof, in particular carbides, nitrides, borides, silicides, C and B₄C.

In a further embodiment, the electrically conductive coating has a thickness of between 50 nm and 1000 nm. The electrically conductive coating can be used to protect the substrate against the damaging influence of the EUV radiation, which otherwise might possibly lead to a degradation of the material of the substrate, that is to say that the electrically conductive coating can serve as a so-called “substrate protection layer”, SPL. For this purpose, it can be advantageous for the electrically conductive coating to have a thickness that is not excessively small.

In a further embodiment, the first layer has a thickness that is greater than the thickness of the second layer, and the material of the first layer has a greater absorption for EUV radiation than the material of the second layer, or vice-versa, that is to say that the second layer has a thickness that is greater than the thickness of the first layer, and the material of the second layer has a greater absorption for EUV radiation than the material of the first layer. In order to protect the substrate against the EUV radiation, it can be advantageous to choose the layer thicknesses of the first and/or the second layer in a suitable manner, for example by applying that (those) layer(s) whose material has a greater absorption for the EUV radiation at the wavelength used with a thickness that is greater than the thickness of that (those) layer(s) comprising a material having a lower absorption for the EUV radiation.

The materials which have a high absorption and which should therefore possibly be applied with a greater thickness for the protection of the substrate can be for example materials selected from the group comprising: iron (Fe), nickel (Ni), cobalt (Co), copper (Cu), silver (Ag), gold (Au), platinum (Pt), tungsten (Wo), chromium (Cr), zinc (Zn), iridium (Ir), indium (In), tin (Sn) and alloys and/or compounds thereof.

In a further embodiment, the electrically conductive coating has at least one section that extends on the substrate laterally beyond an optically used region of the reflective coating or laterally beyond the reflective coating. This is advantageous for electrically contacting the electrically conductive coating. The electrically conductive coating can extend on the top side of the substrate beyond the reflective coating and/or it can extend on a side surface of the substrate beyond the reflective coating. In the section at which the electrically conductive coating extends beyond the reflective coating, the latter can be contacted for example with the aid of an electrical line in order to ground the electrically conductive coating and thus the optical element or in order possibly to measure a photocurrent. The electrical contacting or the grounding of the optical element can advantageously be combined with the protection function described further above for the substrate and the possibly desired production of a predefined layer stress of the electrically conductive coating for compensating for layer stresses in the reflective coating.

In a further embodiment, the reflective coating has a plurality of alternating individual layers composed of materials having different refractive indices. The reflective coating in this case is a multilayer coating having alternating individual layers composed typically of two different materials. The type of materials and the thicknesses of the individual layers are chosen such that the reflective coating has the greatest possible reflectivity at a predefined operating wavelength, for example in the EUV wavelength range. If the operating wavelength is approximately 13.5 nm, then the individual layers usually consist of molybdenum and silicon. In this case, the substrate is typically formed from a so-called zero expansion material having a low coefficient of thermal expansion, for example composed of Zerodur®, Clearceram® or ULE®. The multilayer coating is typically configured for reflecting normal-incidence EUV radiation, i.e. for EUV radiation which is incident on the reflective coating at angles of incidence of typically less than approximately 45° with respect to the surface normal.

As an alternative to the use of a multilayer coating optimized for normal-incidence EUV radiation, it is also possible to use a reflective coating that is configured or optimized for the reflection of grazing-incidence EUV radiation. Grazing incidence of EUV radiation is typically understood to mean incidence of EUV radiation at an angle of incidence of typically more than approximately 60° with respect to the surface normal of the surface of the optical element or of the reflective coating. A reflective coating configured for grazing incidence typically has a reflectivity maximum at at least one angle of incidence that is greater than 60°. A reflective coating of this type typically has at least one layer composed of a material having a low refractive index and a low absorption for the grazing-incidence EUV radiation. The reflective coating or the reflective layer can contain a metallic material or be formed from a metallic material, for example from Mo, Ru or Nb.

Both reflective coatings which are optimized for grazing incidence and reflective coatings which are optimized for normal incidence can contain functional layers, for example barrier layers for preventing diffusion, and also a capping layer for protecting the reflective coating against influences from the environment. The reflective coating can also have an adhesion promoter layer for improving the adhesion of the reflective coating on the electrically conductive coating.

In a further embodiment, at least one protective layer for protecting the substrate against EUV radiation is arranged between the electrically conductive coating and the substrate. As has been described further above, the electrically conductive coating can, if appropriate, itself serve as a protective layer in order to protect the substrate against the incident EUV radiation. If this is only partly successful, a protective layer can additionally be applied between the electrically conductive coating and the substrate. The protective layer typically in turn consists of a conductive material, for example of: iron (Fe), nickel (Ni), cobalt (Co), copper (Cu), silver (Ag), gold (Au), platinum (Pt), tungsten (Wo), chromium (Cr), zinc (Zn), iridium (Ir), indium (In), tin (Sn) and alloys and/or compounds thereof.

The invention also relates to an optical assembly, in particular an EUV lithography system, comprising: at least one optical element as described further above. The optical element can be for example an EUV mirror of an EUV lithography apparatus, which mirror is configured for reflecting EUV radiation.

Further features and advantages of the invention are evident from the following description of exemplary embodiments of the invention, with reference to the figures of the drawing, which show details relevant to the invention and, from the claims. The individual features may be realized in each case individually by themselves or as a plurality in any desired combination in various further embodiments falling within the scope of the invention.

### BRIEF DESCRIPTION OF DRAWINGS

Exemplary embodiments are illustrated in the schematic drawing and are explained in the following description. In the drawing:

FIG. 1 shows a schematic illustration of an EUV lithography apparatus,

FIG. 2 shows a schematic illustration of a reflective optical element comprising an electrically conductive coating consisting of a first layer under a tensile stress,

FIG. 3 shows a schematic illustration analogously to FIG. 2, wherein the electrically conductive coating has a second layer under a compressive stress, which compensates for the tensile stress of the first layer, and

FIG. 4 shows a schematic illustration analogously to FIG. 3, wherein the electrically conductive coating extends on the top side of the substrate laterally beyond the reflective coating.

### DETAILED DESCRIPTION

In the following description of the drawings, identical reference signs are used for identical, functionally identical or equivalent components.

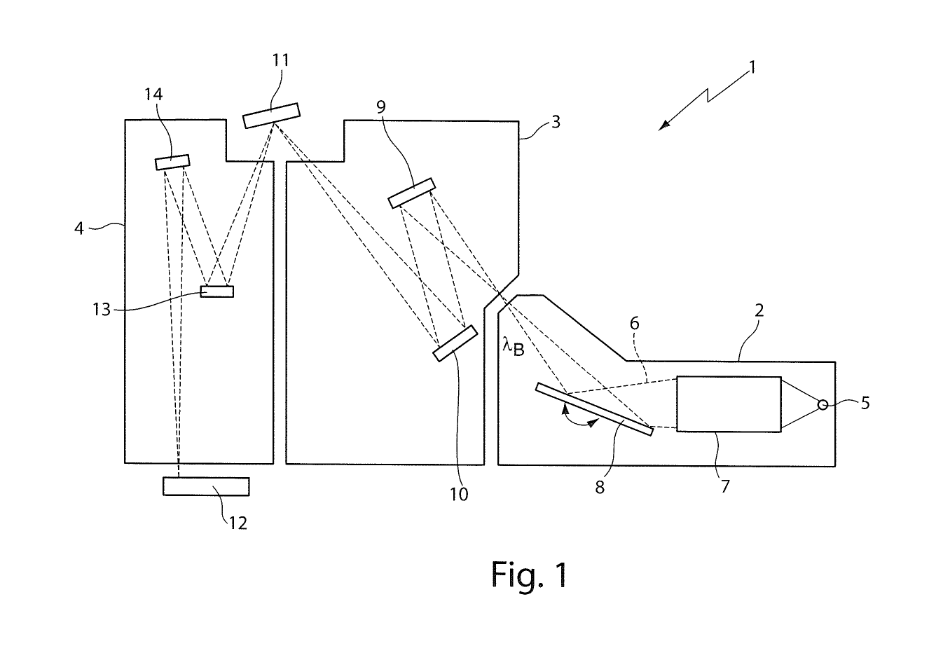

FIG. 1 schematically shows an EUV lithography system in the form of a projection exposure apparatus 1 for EUV lithography. The projection exposure apparatus 1 comprises a beam shaping system 2, an illumination system 3 and a projection system 4, which are accommodated in separate vacuum housings and arranged successively in a beam path 6 emanating from an EUV light source 5 of the beam shaping system 2. A plasma source or a synchrotron can serve for example as the EUV light source 5. The radiation emerging from the light source 5 in the wavelength range between about 5 nm and about 20 nm is first focused in a collimator 7. With the aid of a downstream monochromator 8, the desired operating wavelength X,B, which in the present example is about 13.5 nm, is filtered out by variation of the angle of incidence, as indicated by a double-headed arrow. The collimator 7 and the monochromator 8 are configured as reflective optical elements.

The radiation treated with regard to wavelength and spatial distribution in the beam shaping system 2 is introduced into the illumination system 3, which has a first and a second reflective optical element 9, 10. The two reflective optical elements 9, 10 guide the EUV radiation onto a photomask 11 as further reflective optical element, which has a structure that is imaged onto a wafer 12 on a reduced scale with the projection system 4. For this purpose, a third and a fourth reflective optical element 13, 14 are provided in the projection system 4.

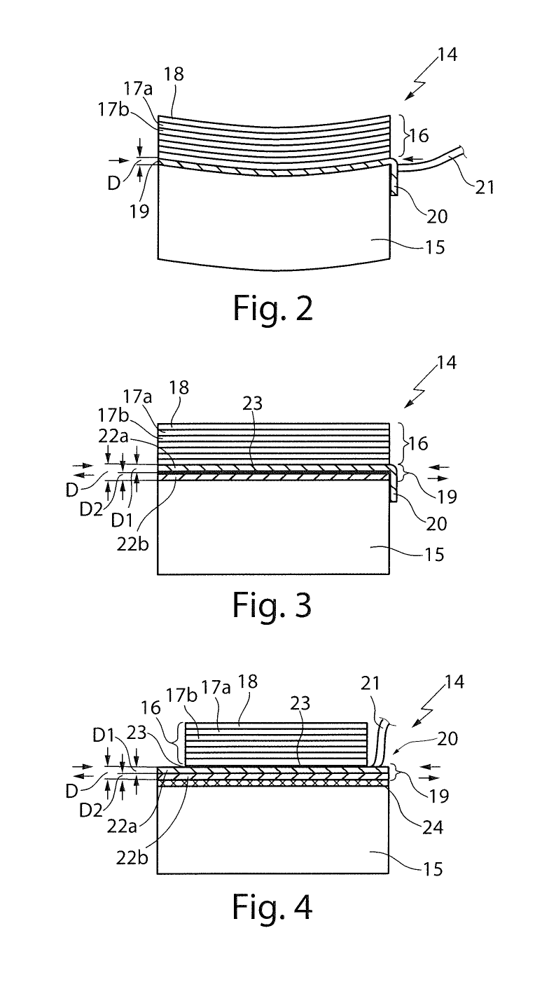

The design of the fourth optical element 14 is described in greater detail by way of example below with reference to FIG. 2 to FIG. 4; the first to third optical elements 11, 12, 13 have a corresponding design. The (fourth) optical element 14 comprises a substrate 15 composed of a material having a low coefficient of thermal expansion, which is typically less than 100 ppb/K at 22° C. or over a temperature range of approximately 5° C. to approximately 35° C. One material which has these properties is silicate or quartz glass doped with titanium dioxide and typically having a silicate glass proportion of more than 90%. Such a commercially available silicate glass is sold by Corning Inc. under the trade name ULE® (Ultra Low Expansion glass). A further material group having a very low coefficient of thermal expansion is that of glass ceramics, in which the ratio of the crystal phase to the glass phase is set such that the coefficients of thermal expansion of the different phases nearly cancel one another out. Such glass ceramics are offered for example under the trade name Zerodur® by Schott AG or under the trade name Clearceram® by Ohara Inc.

A reflective coating 16 having a plurality of individual layers 17a, 17b consisting of different materials is applied on the substrate 15. In the present case, the individual layers alternately consist of materials having different refractive indices. If the operating wavelength kB is approximately 13.5 nm, as in the present case, then the individual layers usually consist of molybdenum and silicon. Other material combinations such as e.g. molybdenum and beryllium, ruthenium and beryllium or lanthanum and B₄C are likewise possible. In addition to the individual layers described, the reflective coating 16 can also comprise intermediate layers and/or barrier layers for preventing diffusion. The illustration of such auxiliary layers has been omitted in the figures.

The reflective coating 16 also has a capping layer 18 in order to protect the underlying individual layers 17a, 17b and to prevent for example the oxidation thereof. The capping layer 18 consists of ruthenium in the present example. Other materials, in particular metallic materials such as rhodium, palladium, platinum, iridium, niobium, vanadium, chromium, zinc or tin, can also be used as capping layer materials. The capping layer 18 is transmissive to the EUV radiation 6.

As an alternative to the reflective coating 16 shown in FIG. 2, which is configured for normal-incidence EUV radiation 6, the reflective coating 16 can be configured or optimized for grazing-incidence EUV radiation 6. In this case, the reflective coating 16 can comprise, if appropriate, just a single layer, which can be formed for example from a metallic material, in particular from Mo, Ru or Nb.

In the case of the example shown in FIG. 2, an electrically conductive coating 19 consisting just of a single layer composed of a noble metal, composed of gold in the example shown, is arranged between the reflective coating 16 and the substrate 15. In the case of the example shown in FIG. 2, the electrically conductive coating 19 has a section that extends on a side surface of the substrate 15 in order to be able to electrically contact the electrically conductive coating 19. In the case of the example shown in FIG. 2, the electrical contacting is effected with an electrical line 21, which can be connected to ground potential, for example, in order to ground the optical element 14. The line 21 can also serve to conduct a photocurrent, generated in the reflective coating 16 as a result of the irradiation with the EUV radiation 6, away from the optical element 14 and to measure the photocurrent in a charge amplifier, for example.

The electrically conductive coating 19 is produced with the aid of conventional coating methods, specifically typically by “Physical Vapor Deposition” (PVD) methods such as e.g. thermal evaporation or electron beam evaporation, ion beam or magnetron sputtering or pulsed laser deposition, or coating methods based on “Chemical Vapor Deposition” (CVD). When the electrically conductive coating 19 is applied, a layer stress is produced which, in the case of the example shown in FIG. 2, wherein gold is used as material for the electrically conductive coating 19, leads to a tensile stress in the electrically conductive coating, as is indicated by two lateral arrows at the electrically conductive coating 19 in FIG. 2.

In the case of the thickness D of typically between approximately 50 nm and approximately 1000 nm, approximately 300 nm in the example shown, that is typically used for the electrically conductive coating 19, the tensile stress has the consequence that the substrate 15 warps, such that the latter forms a concave curvature at its side facing the reflective coating 16, said concave curvature being illustrated in a greatly exaggerated manner for elucidation purposes in FIG. 2. The electrically conductive layer 19 thus leads to a deviation of the surface shape of the optical element 14 from a desired surface shape (desired figure), which is a plane surface shape in the case of the example shown in FIG. 2. The deviation from the desired surface shape leads to aberrations of the optical element 14 during operation in the EUV lithography apparatus 1.

In order to avoid the undesired deformation of the substrate 15 and thus of the surface shape of the optical element 14, in the case of the example illustrated in FIG. 3, the electrically conductive coating 19 has a first layer 22a under a tensile stress and a second layer 22b under a compressive stress. The first layer 22a under the tensile stress and/or the second layer 22b under compressive stress can be formed for example from a material selected from the group comprising: silver, copper, gold, aluminum, rhodium, iridium, tungsten, molybdenum, cobalt, nickel, ruthenium, indium, osmium, iron, platinum, palladium, chromium, tantalum, titanium, Zr, Re. Both the first and the second layer 22a, 22b of the electrically conductive coating 19 can e.g. also be formed from an (electrically conductive) alloy instead of a metallic material. The fact of whether the first and/or second layer 22a, 22b are/is under a tensile stress or a compressive stress, depends not only on the material used but also on the coating method by which the respective material is applied. In the example shown, the first layer 22a, which consists of gold, is applied by electron beam evaporation, as a result of which a tensile stress is formed in the first layer 22a. In the example shown, the second layer 22b consists of ruthenium and was produced by sputtering, as a result of which a compressive stress is formed in the ruthenium material of the second layer 22b.

In the case of the example shown in FIG. 3, the tensile stress of the first layer 22a and the compressive stress of the second layer 22b are chosen such that the resulting layer stress of the electrically conductive coating 19 substantially disappears, with the result that the plane desired surface shape of the substrate 15 and thus also of the reflective surface of the optical element 14 is produced.

This makes use of the fact that the second layer 22b under compressive stress produces a warping of the substrate that is directed oppositely to the warping as a result of the first layer 22a under tensile stress, since the second layer 22b under compressive stress brings about a convex curvature of the substrate 15. In order to produce the compensation of the layer stresses of the electrically conductive coating 19, the layer materials and the thicknesses of the first and second layers 22a, 22b are suitably adapted to one another.

As can likewise be discerned in FIG. 3, a barrier layer 23 is arranged between the first layer 22a under tensile stress and the second layer 22b under compressive stress, said barrier layer being intended to substantially prevent a diffusion of the material of the first layer 22a into the second layer 22b (and vice-versa). The barrier layer 23 typically has such a small thickness (e.g. of less than 1 nm) that its layer stress on the electrically conductive coating 19 is practically negligible. However, if necessary, the influence of the tensile and/or the compressive stress of the barrier layer 23 on the resulting layer stress of the electrically conductive coating 19 must be taken into account. The electrically conductive coating 19 can have, if appropriate, more than one layer 22a under a tensile stress and more than one layer 22b under a compressive stress, and, if appropriate, further barrier layers. The material of the barrier layer 23 can be selected for example from the group comprising: W, Ta, Y, Mo, Zr, Ti, Hf, Sc, alloys and/or compounds thereof, in particular carbides, nitrides, borides, silicides, C and B₄C.

Instead of a substantially complete compensation of the layer stresses of the layers 22a, 22b under tensile and respectively under compressive stress, it is also possible, with the aid of the electrically conductive coating 19, to produce a predefined resulting layer stress that can be used to wholly or partly compensate for layer stresses that occur in the reflective coating 16 as a result of the coating process. In order to be able to compensate for possibly locally varying layer stresses in the reflective coating 16, the electrically conductive coating 19 can exhibit a location-dependent variation of the thickness of the individual layers 22a, 22b under tensile and respectively under compressive stress. Such a possibly location-dependent variation of the layer thicknesses and/or of the layer materials used and/or of the composition of the layers 22a, 22b can, if appropriate, also be carried out for other reasons, for example in order to achieve protection against the influence of the EUV radiation 6 on the substrate 15.

In order to protect the substrate 15 against the EUV radiation 6, those layers 22a, 22b of the electrically conductive coating 19 which have a high absorption for the EUV radiation 6 should ideally have a larger thickness than those layers 22a, 22b which have a low absorption for the EUV radiation 6. In the case of the example shown in FIG. 2, the first layer 22a, which consists of gold, can have for example a thickness D1 that is greater than the thickness D2 of the second layer 22b, which consists of ruthenium, since gold has a greater absorption for the EUV radiation 6 than ruthenium. Materials that should be applied with a greater thickness in order to protect the substrate 15 can be selected for example from the group comprising: Fe, Ni, Co, Cu, Ag, Au, Pt, Wo, Cr, Zn, Ir, In, Sn and alloys and/or compounds thereof.

In the case of the example shown in FIG. 3, the electrically conductive coating 19, as in the case of the example shown in FIG. 2, has a section 20 that extends on the substrate 15 laterally beyond the reflective coating 16, specifically as in FIG. 2 along a side surface of the substrate 15. As in FIG. 2, the projecting section 20 serves for electrically contacting the electrically conductive coating 19. Instead of the section 20 of the electrically conductive coating 19, in the case of the example shown in FIG. 3, it is also possible for just a portion, for example a single one, of the layers 22a, 22b to project on the side surface of the substrate 15 beyond the reflective coating 16, since in this region the influence of the tensile and/or the compressive stress on the surface shape of the optical element 14 is typically less than on the top side of the substrate 15. In general, however, it is more advantageous for the entire (stress-compensated) electrically conductive coating 19 to form the projecting section 20, as is illustrated in FIG. 3.

FIG. 4 shows a further example of an optical element 14, which differs from the optical element 14 shown in FIG. 3 in that the electrically conductive coating 19 has a section 20 which projects laterally beyond the reflective coating 16 and which is not formed on the side surface of the substrate 15, but rather on the top side thereof. As can be discerned in FIG. 4, in this case the electrically conductive coating 19 on the top side of the substrate 15 can be contacted with an electrical line 21 in order to ground the optical element 14 and, if appropriate, to conduct a photocurrent away from the latter.

In the case of the example shown in FIG. 4, a barrier layer 23 is additionally formed between the reflective coating 16 and the electrically conductive coating 19 in order to prevent the diffusion of material from the reflective coating 16 into the electrically conductive coating 19 (and vice-versa). In the example shown, the barrier layer 23 consists of carbon, but can also be formed from some other material, for example from W, Ta, B₄C or Mo.

In the case of the example shown in FIG. 4, a protective layer 24 is formed between the electrically conductive coating 19 and the substrate 15, said protective layer serving for protecting the substrate 15 against the EUV radiation 6. This may be necessary if the electrically conductive coating 19 does not sufficiently absorb the EUV radiation 6, such that the latter can pass to the substrate 15. The protective layer 24 in turn typically consists of a conductive material, for example of: iron (Fe), nickel (Ni), cobalt (Co), copper (Cu), silver (Ag), gold (Au), platinum (Pt), tungsten (Wo), chromium (Cr), zinc (Zn), iridium (Ir), indium (In), tin (Sn) and alloys and/or compounds thereof. The layer stress of the protective layer 24 can be disregarded, if appropriate, but can also be taken into account, if appropriate, in the compensation of the layer stresses as described further above.

With the electrically conductive coating 19 described further above, the optical element 14 can be grounded without its optical properties being impaired. Moreover, the electrically conductive coating 19 can have a defined bias voltage applied to it or be used for conducting away a photocurrent. The electrically conductive coating 19 can in particular also serve for protecting the substrate 15 against the EUV radiation 6.

1. An optical element, comprising:
a substrate,
a reflective coating arranged on the substrate, and
an electrically conductive coating extending between the substrate and the reflective coating,
wherein the electrically conductive coating has at least one first layer under tensile stress and at least one second layer under compressive stress, and
wherein the electrically conductive coating has at least one section that extends on the substrate laterally beyond the reflective coating.

2. The optical element as claimed in claim 1 and configured to reflect extreme ultraviolet (EUV) light.

3. The optical element as claimed in claim 1, wherein the first and/or the second layer are/is formed from a metallic material or a metallic alloy.

4. The optical element as claimed in claim 1, wherein a material of the first layer and/or a material of the second layer are/is selected from the group comprising: silver, copper, gold, aluminum, rhodium, iridium, tungsten, molybdenum, cobalt, nickel, ruthenium, indium, osmium, iron, platinum, palladium, chromium, tantalum, titanium, Zr, Re and alloys thereof.

5. The optical element as claimed in claim 1, wherein the electrically conductive coating comprises at least one barrier layer that is arranged between the first layer and the second layer.

6. The optical element as claimed in claim 1, further comprising at least one barrier layer arranged between the reflective coating and the electrically conductive coating.

7. The optical element as claimed in claim 5, wherein a material of the barrier layer is selected from the group comprising: W, Ta, Y, Mo, Zr, Ti, Hf, Sc, alloys and/or compounds thereof.

8. The optical element as claimed in claim 7, wherein the material of the barrier layer is selected from the group comprising: carbides, nitrides, borides, silicides, C and B₄C.

9. The optical element as claimed in claim 6, wherein a material of the barrier layer is selected from the group comprising: W, Ta, Y, Mo, Zr, Ti, Hf, Sc, alloys and/or compounds thereof.

10. The optical element as claimed in claim 9, wherein the material of the barrier layer is selected from the group comprising: carbides, nitrides, borides, silicides, C and B₄C.

11. The optical element as claimed in claim 1, wherein the electrically conductive coating has a thickness of between 50 nm and 1000 nm.

12. The optical element as claimed in claim 1, wherein the first layer has a thickness that is greater than a thickness of the second layer, and wherein a material of the first layer has an absorption for EUV radiation that is greater than an absorption for the EUV radiation of a material of the second layer.

13. The optical element as claimed in claim 1, wherein the second layer has a thickness that is greater than the thickness of the first layer, and wherein a material of the second layer has an absorption for EUV radiation that is greater than an absorption for the EUV radiation of a material of the first layer.

14. The optical element as claimed in claim 1, wherein the reflective coating comprises a plurality of alternating individual layers composed of materials having mutually different refractive indices.

15. The optical element as claimed in claim 1, further comprising at least one protective layer configured to protect the substrate against EUV radiation and arranged between the electrically conductive coating and the substrate.

16. An optical assembly, comprising: at least one optical element as claimed in claim 1.

17. The optical assembly as claimed in claim 16, configured as an EUV lithography system and comprising:
a beam shaping system,
an illumination system, and
a projection system comprising the at least one optical element.

18. The optical assembly as claimed in claim 16, further comprising: an electrical line configured to contact the at least one section of the electrically conductive coating that extends on the substrate laterally beyond the reflective coating.
